(19) United States
(12) Patent Application Publication
(10) Pub. No.: US 2009/0311872 A1
(43) Pub. Date: Dec. 17, 2009

(54) GAS RING, APPARATUS FOR PROCESSING SEMICONDUCTOR SUBSTRATE, THE APPARATUS INCLUDING THE GAS RING, AND METHOD OF PROCESSING SEMICONDUCTOR SUBSTRATE BY USING THE APPARATUS

(75) Inventors: Hirokazu UEDA, Amagasaki City (JP); Yoshinobu TANAKA, Amagasaki City (JP); Yasuhiro OTSUKA, Amagasaki City (JP); Masanobu NAKAHASHI, Osaka City (JP)

Correspondence Address: CANTOR COLBURN, LLP, 20 Church Street, 22nd Floor, Hartford, CT, 06103, US

(73) Assignee: TOKYO ELECTRON LIMITED, Tokyo (JP)

(21) Appl. No.: 12/483,573

(22) Filed: Jun. 12, 2009

(30) Foreign Application Priority Data
Jun. 13, 2008 (JP) 2008-155561

(51) Int. Cl. H01L 21/465; B05B 1/14; C23C 16/455; C23C 16/511; H01L 21/46; C23F 1/08

(52) U.S. Cl. 438/726; 239/589; 118/723 R; 118/723 MW; 438/758; 156/345.33; 257/E21.482; 257/E21.485

(57) ABSTRACT

A gas ring has a ring shape and includes: a gas inlet hole through which a gas is introduced from outside the gas inlet hole into the gas ring; a plurality of gas jets that ejects the gas transferred from the gas inlet hole; and a plurality of branched paths extending along the ring shape from the gas inlet hole to each of the plurality of gas jets. Here, distances between each of the plurality of gas jets to central parts, which are branch points of each of the plurality of branched paths, are identical to each other.

### CROSS-REFERENCE TO RELATED PATENT APPLICATIONS

This application claims the benefit of Japanese Patent Application No. 2008-155561, filed on Jun. 13, 2008, in the Japan Patent Office, the disclosure of which is incorporated herein in its entirety by reference.

### BACKGROUND OF THE INVENTION

1. Field of the Invention

The present invention relates to a gas ring, an apparatus for processing a semiconductor substrate, and a method of processing a semiconductor substrate, and more particularly, to a gas ring including a plurality of gas jets, an apparatus for processing a semiconductor substrate, the apparatus including the gas ring, and a method of processing a semiconductor substrate by using the apparatus including the gas ring.

2. Description of the Related Art

A semiconductor device, such as a large scale integrated circuit (LSI), is manufactured by performing a plurality of processes such as etching, chemical vapor deposition (CVD), and sputtering processes on a substrate to be processed. In detail, for example, a process reaction gas is supplied into a processing container in which plasma is generated, and a film is formed on the substrate to be processed via a CVD process, or an etching process is performed on the substrate to be processed.

Here, when the process reaction gas is supplied into the processing container, a gas shower head (a gas ring) may be used to supply the process reaction gas by ejecting the process reaction gas toward the substrate to be processed. FIG. 16 is a diagram of an example of a conventional gas shower head 101. Referring to FIG. 16, the gas shower head 101 has a shape wherein a glass tube is bent to form a round ring shape. The gas shower head 101 includes a gas inlet hole 102, through which a gas from outside the gas shower head 101 is introduced into the gas shower head 101, and 16 gas jets, which eject the gas introduced via the gas inlet hole 102. Each of the 16 gas jets is formed to be opened on an internal diameter of a body unit 104 of a round ring shape. Also, the 16 gas jets are equally spaced apart from each other along a circumferential direction. The gas is introduced from the gas inlet hole 102, passes inside the body unit 104, and is ejected toward an internal diameter of the gas shower head 101 via the gas jets.

A heat-treating apparatus that includes the gas shower head 101 having such a structure and which processes a semiconductor substrate is disclosed in Japanese Laid-Open Patent Publication No. 2000-182974 (hereinafter, referred to as Cited Reference R1).

Also, WO 00/74127 (hereinafter, referred to as Cited Reference R2) discloses a gas shower head used in a plasma process device that performs a plasma process on a substrate to be processed. As shown in FIG. 17, a gas shower head 111 disclosed in the Cited Reference R2 is formed of a quartz pipe, in which a gas path 112 including a plurality of gas jets 113 has a lattice shape. Intervals between the plurality of gas jets 113 are identical to each other.

In the case of the gas shower head 101 disclosed in Cited Reference R1, it is difficult to uniformly eject a gas introduced via the gas inlet hole 102 through the plurality of gas jets. The gas is introduced into the gas shower head 101 from the gas inlet hole 101 at a predetermined pressure and a predetermined flow rate, as indicated by an arrow Z₁. Here, gas jets 103a, 103b, and 103c near the gas inlet hole 102 eject the gas in directions indicated by arrows Z₂ while almost maintaining the predetermined pressure and flow rate. However, gas jets 103d, 130e, and 103f far from the gas inlet hole 102 eject the gas in directions indicated by arrows Z₃ at a pressure and flow rate lower than the predetermined pressure and flow rate, due to pressure loss or the like. As such, the pressure and flow rate of the gas ejected from the gas jets 103a, 103b, and 103c near the gas inlet hole 102, and the pressure and the flow rate of the gas ejected from the gas jets 103d, 103e, and 103f far from the gas inlet hole 102 are different from each other, and thus the gas is not uniformly ejected from the gas jets 103a through 103f.

In this case, it is possible to uniformly eject a gas from the gas jets by, for example, changing the diameters of the gas jets according to a type, pressure, and flow rate of the gas. However, when conditions such as the type, pressure, and flow rate of the gas change, it is difficult to uniformly eject the gas.

Also, according to an apparatus for processing a semiconductor substrate, wherein the apparatus includes the gas shower head 101, a gas is not uniformly ejected from each gas jet to a substrate to be processed, and thus an etching or CVD process is not suitably performed on the substrate to be processed.

### SUMMARY OF THE INVENTION

To solve the above and/or other problems, the present invention provides a gas ring that uniformly ejects a gas from each of a plurality of gas jets.

To solve the above and/or other problems, the present invention also provides an apparatus for processing a semiconductor substrate that suitably performs an etching process or a chemical vapor deposition (CVD) process on a substrate to be processed.

To solve the above and/or other problems, the present invention also provides a method of processing a semiconductor substrate, whereby an etching process or a CVD process is suitably performed on a substrate to be processed.

According to an aspect of the present invention, there is provided a gas ring having a ring shape, the gas ring including: a gas inlet hole through which a gas is introduced from outside the gas inlet hole into the gas ring; a plurality of gas jets that eject the gas introduced from the gas inlet hole; a plurality of branched paths extending along the ring shape from the gas inlet hole to each of the plurality of gas jets, wherein distances between each of the plurality of gas jets to branch points of each of the plurality of branched paths are identical to each other.

According to the gas ring, since the distances between each of the plurality of gas jets to the branch points of each of the branched paths are the same, pressures or flow rates of the gas ejected from each of the plurality of gas jets are the same. Accordingly, the gas is uniformly ejected from each of the plurality of gas jets.

The gas ring may have a round ring shape.

The plurality of gas jets may be equally spaced apart from each other.

Flow passage resistances (conductance) from each of the plurality of gas jets to the branch points may be the same.

Each of the plurality of gas jets may have a circular shape, and diameters of the plurality of gas jets having the circular shape may be the same.

According to another aspect of the present invention, there is provided an apparatus for processing a semiconductor substrate, the apparatus including: a processing container for processing a substrate to be processed inside the processing container; a holding stage that is disposed inside the processing container and holds the substrate to be processed thereon; a plasma generating means that generates plasma inside the processing container; and a reaction gas supplier that supplies a reaction gas for a process toward the substrate to be processed held by the holding stage, wherein the reaction gas supplier includes: an injector that ejects the reaction gas toward a center area of the substrate to be processed held by the holding stage; and the gas ring of above that ejects the reaction gas toward an edge area of the substrate to be processed held by the holding stage, wherein the gas ring is disposed at a location other than an area right above the substrate to be processed held by the holding stage.

The plasma generating means may include: a microwave generator that generates microwaves for exciting plasma; and a dielectric plate that is disposed at a location facing the holding stage and transmits the microwaves into the processing container.

In the apparatus that performs an etching process or a CVD process on the substrate to be processed, when the reaction gas for processing the substrate to be processed is supplied via the gas shower head 101 illustrated in FIG. 16, the reaction gas cannot be uniformly ejected from each gas jet, and thus it is difficult to uniformly perform the etching process or the CVD process on the substrate to be processed.

Also, the following problems may occur. FIG. 18 is a cross-sectional view schematically illustrating a part of a conventional plasma processing apparatus 121 as an apparatus for processing a semiconductor substrate including the gas shower head 101 of FIG. 16. Referring to FIG. 18, the conventional plasma processing apparatus 121 uses microwaves as a plasma source. The gas shower head 101 included in the conventional plasma processing apparatus 121 is disposed on a holding stage 122 that holds a substrate W to be processed. The gas shower head 101 is disposed in an area 125 right above the substrate W held on the holding stage 122.

In the conventional plasma processing apparatus 121, plasma is generated right below a dielectric plate (top plate) 124 that is formed of a dielectric and transmits microwaves into a processing container 123 of the conventional plasma processing apparatus 121. The generated plasma diffuses toward a lower side of the dielectric plate 124. Here, when the gas shower plate 101 is disposed in the area 125 right above the substrate W held on the holding stage 122, plasma in the area 125 right above the substrate W becomes non-uniform due to plasma shielding by the gas shower head 101. In this case, the substrate W is processed non-uniformly. In other words, a process performed on the substrate W is performed non-uniformly. Also, when the gas shower head 111 disclosed in Cited Reference 2 and illustrated in FIG. 17 is used, the gas path 112 having a lattice shape also shields plasma, and thus plasma is non-uniform in the area 125 right above the substrate W.

However, according to the apparatus of above, the gas ring is placed in an area other than an area right above the substrate to be processed, and thus a shielding in the area right above the substrate to be processed may be removed. Accordingly, plasma in the area right above the substrate to be processed is uniform. Also, by using the gas ring and the injector, the reaction gas may be uniformly ejected on each portion of the substrate to be processed. Accordingly, a processing speed variation of the substrate to be processed may be uniform.

When the substrate to be processed has a circular plate shape, the gas ring may have a circular ring shape and an internal diameter of the gas ring may be greater than an outer diameter of the substrate to be processed. Accordingly, the gas ring may be placed in other area than the area right above the substrate to be processed having the circular plate shape.

The processing container may include a bottom part disposed below the holding stage and a side wall extending upwardly from a circumference of the bottom part, and the gas ring may be embedded inside the side wall.

According to another aspect of the present invention, there is provided a method of processing a semiconductor substrate, whereby the semiconductor substrate is manufactured by processing a substrate to be processed, the method including: preparing an injector, which ejects a reaction gas for a process toward a center area of the substrate to be processed, and the gas ring of above, which ejects the reaction gas toward an edge area of the substrate to be processed; holding the substrate to be processed on a holding stage disposed inside a processing container; generating plasma inside the processing container; and ejecting the reaction gas from the injector and the gas ring toward the substrate to be processed, and processing the substrate to be processed by using the generated plasma.

According to the method, the reaction gas may be uniformly ejected onto the substrate to be processed, and thus the substrate to be processed may be uniformly processed.

### BRIEF DESCRIPTION OF THE DRAWINGS

The above and other features and advantages of the present invention will become more apparent by describing in detail exemplary embodiments thereof with reference to the attached drawings in which:

FIG. 1 is a diagram of a gas ring according to an embodiment of the present invention;

FIG. 2 is a cross-sectional view of the gas ring of FIG. 1 taken along a line II-II in FIG. 1;

FIG. 3 is an enlarged diagram of an area III of FIG. 2;

FIG. 4 is an enlarged diagram of an area IV of FIG. 2;

FIG. 5 is a cross-sectional view of the gas ring of FIG. 1 taken along a line V-V in FIG. 1;

FIG. 6 is an enlarged diagram of an area VI of FIG. 1;

FIG. 7 is a diagram of the gas ring of FIG. 1 viewed from a direction indicated by an arrow VII in FIG. 1;

FIG. 8 is a cross-sectional view schematically illustrating main parts of a plasma processing apparatus including a gas ring, according to an embodiment of the present invention;

FIG. 9 is a diagram illustrating a conventional gas shower head;

FIG. 10 is a diagram showing a thickness distribution of a layer of a semiconductor substrate, when a CVD process is performed by using the conventional gas shower head of FIG. 9;

FIG. 11 is a diagram showing a thickness distribution of a layer of a semiconductor substrate, when a CVD process is performed by using a plasma processing apparatus according to an embodiment of the present invention;

FIG. 12 is a graph of a thickness of the layer with respect to a location of the layer on the semiconductor substrate of FIG. 10;

FIG. 13 is a graph of a thickness of the layer with respect to a location of the layer on the semiconductor substrate of FIG. 11;

FIG. 14 is a diagram showing the X-axis, Y-axis, V-axis, and W-axis of FIGS. 12 and 13 indicated on a semiconductor substrate;

FIG. 15 is an enlarged cross-sectional view of a part of a plasma processing apparatus, according to an embodiment of the present invention;

FIG. 16 is a diagram of an example of a conventional gas shower head;

FIG. 17 is a diagram of a conventional gas shower head having a lattice shape;and FIG. 18 is a cross-sectional view schematically illustrating a part of a conventional plasma processing apparatus as an apparatus for processing a semiconductor substrate, wherein the apparatus includes the gas shower head of FIG. 16.

### DETAILED DESCRIPTION OF THE INVENTION

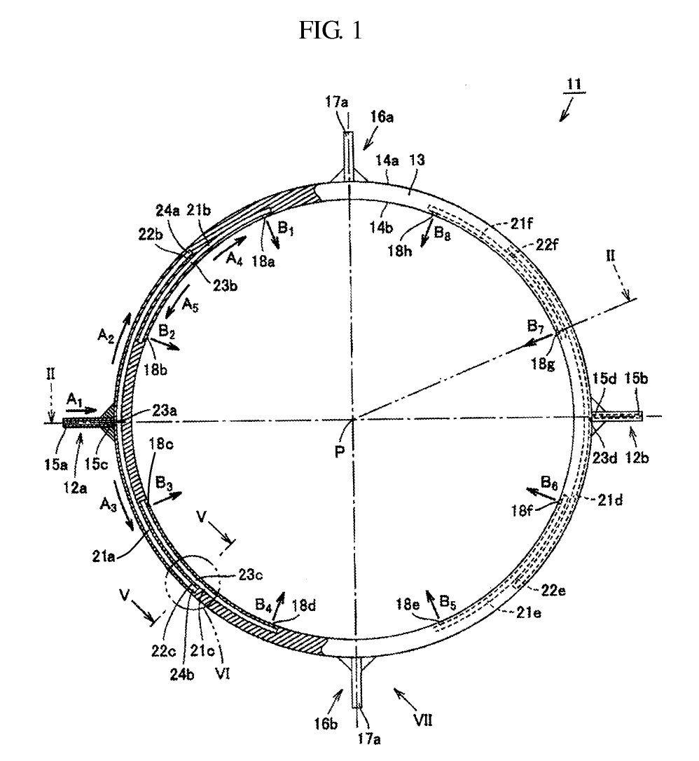

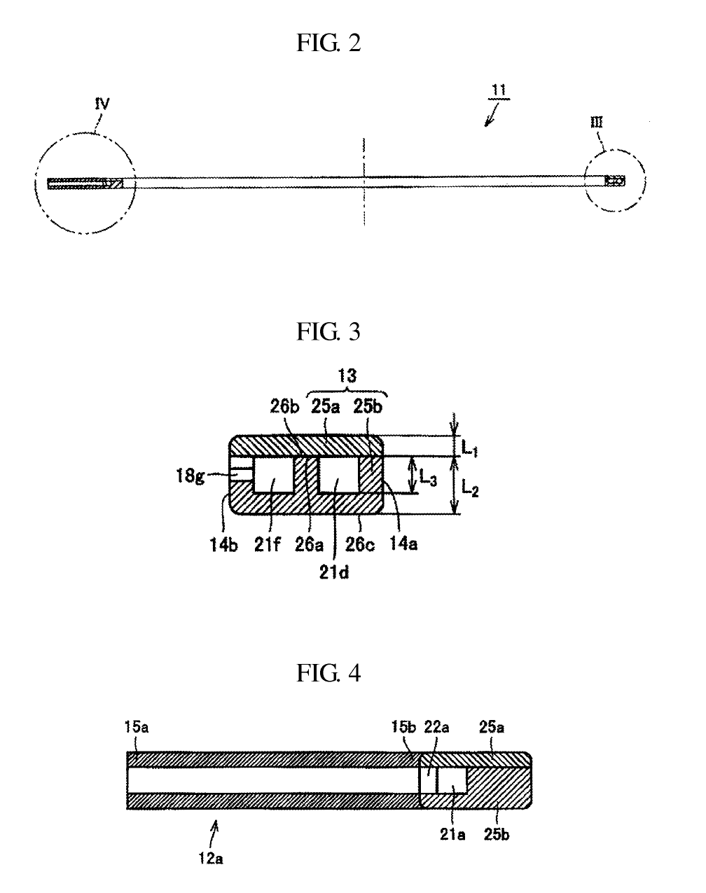

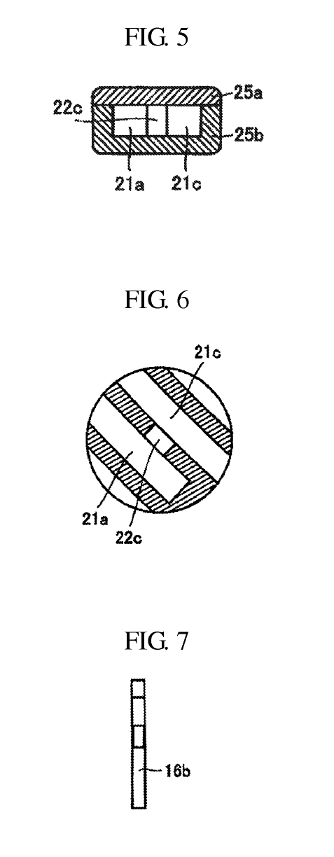

Hereinafter, embodiments of the present invention will be described with reference to the attached drawings. FIG. 1 is a diagram of a gas ring 11 according to an embodiment of the present invention. FIG. 2 is a cross-sectional view of the gas ring 11 of FIG. 1 taken along a line II-II in FIG. 1. FIG. 3 is an enlarged diagram of an area III of FIG. 2. FIG. 4 is an enlarged diagram of an area IV of FIG. 2. FIG. 5 is a cross-sectional view of the gas ring 11 of FIG. 1 taken along a line V-V in FIG. 1. FIG. 6 is an enlarged diagram of an area VI of FIG. 1. FIG. 7 is a diagram of the gas ring 11 of FIG. 1 viewed from a direction indicated by an arrow VII of FIG. 1. For convenience of understanding, a part of the gas ring 11 in FIG. 1 is illustrated in a sectional view.

Referring to FIGS. 1 through 7, the gas ring 11 is mainly used as an element for supplying a reaction gas when an etching process or a chemical vapor deposition (CVD) process is performed on a substrate to be processed into a semiconductor substrate in order to manufacture a semiconductor device. A detailed structure of an apparatus for processing a semiconductor substrate, the apparatus including a gas ring, will be described later.

The gas ring 11 has a round ring shape. In other words, a body unit 13 of the gas ring 11 has a round ring shape. An internal diameter of the gas ring 11, for example, is 300 mm. An outer diameter of the gas ring 11, for example, is 320 mm. A material of the gas ring 11, for example, is quartz glass.

The gas ring 11 includes two gas inlet holes 12a and 12b, which transfer a gas outside the gas ring 11 into the gas ring 11. Each of the gas inlet holes 12a and 12b has a straight pipe shape, and here, has a shape extending in right and left sides of FIG. 1, and is hollow. Each of the gas inlet holes 12a and 12b is formed to protrude from an external circumference surface 14a of the body unit 13 having the round ring shape to an external circumference side of the body unit 13. The gas inlet holes 12a and 12b are respectively formed at locations that face each other with an angle of 180° therebetween with respect to a center P of the body unit 13 having the round ring shape. A gas is respectively introduced into the gas ring 11 from edges 15a and 15b of the external circumference side of the gas inlet holes 12a and 12b. Also, a pressure or a flow rate of the gas introduced into the gas inlet holes 12a and 12b is the same.

The gas ring 11 includes two supports 16a and 16b supporting the body unit 13 of the gas ring 11. The supports 16a and 16b are not hollow, and have a straight rod shape. The supports 16a and 16b are respectively disposed at locations that face each other with an angle of 180° therebetween with respect to the center P of the body unit 13 having the round ring shape. The supports 16a and 16b are respectively disposed at locations at angles of 90° from the gas inlet holes 12a and 12b, with respect to the center P. In other words, the gas inlet holes 12a and 12b, and the supports 16a and 16b are each disposed at locations at angles of 90° from each other with respect to the center P, around the external circumference surface 14a of the body unit 13. The body unit 13 of the gas ring 11 is supported by attaching edges 17a and 17b on the external circumference side of the supports 16a and 16b to other members (not shown) disposed on the external circumference side of the gas ring 11

The gas ring 11 includes eight gas jets 18a, 18b, 18c, 18d, 18e, 18f, 18g, and 18h, which eject the gas introduced into the body unit 13 via the gas inlet holes 12a and 12b. Each of the gas jets 18a through 18h is formed on the internal circumference side of the body unit 13. In detail, each of the gas jets 18a through 18h is formed to be opened toward an internal circumference surface 14b of the body unit 13. The gas introduced into the body unit 13 via the gas inlet hole 12a is ejected toward an internal space of the gas ring 11 as indicated by arrows B₁, B₂, B₃, and B₄ from four of the gas jets 18a, 18b, 18c, and 18d. The gas introduced into the body unit 13 via the gas inlet hole 12b is ejected toward the internal space of the gas ring 11 as indicated by arrows B₅, B₆, B₇, and B₈ from the 4 gas jets 18e, 18f, 18g, and 18h.

The gas jets 18a through 18h are equally spaced apart from each other. Here, the gas jets 18a through 18h are equally spaced apart from each other in a circumferential direction of the body unit 13 having the round ring shape.

Each of the gas jets 18a through 18h is formed to have a circular shape. Here, in the circular shape, the center thereof is located in the center of the body unit 13 in a thickness direction thereof. Also, diameters of the gas jets 18a through 18h having the circular shapes are the same. Each of the diameters of the gas jets 18a through 18h is, for example, φ1 mm.

The gas ring 11 includes a plurality of branched paths 21a, 21b, and 21c that extend along the body unit 13 of the ring shape from the gas inlet hole 12a to each of the gas jets 18a through 18d. Similarly, the gas ring 11 includes a plurality of branched paths 21d, 21e, and 21f that extend along the body unit 13 of the ring shape from the gas inlet hole 21b to each of the gas jets 18e through 18h.

A structure of the branched paths will now be described. The branched paths include a first branched path 21a leading from the gas inlet hole 12a, a second branched path 21b leading from the first branched path 21a to the gas jets 18a and 18b, and a second branched path 21c leading from the first branched path 21a to the gas jets 18c and 18d. The second branched paths 21b and 21c are each disposed on an internal circumference side of the first branched path 21a.

The first branched path 21a has a shape that extends along the body unit 13 having the round ring shape. In other words, the first branched path 21a has a circular arc shape. The circumferential distance of the first branched path 21a is ¼ of the circumference of the body unit 13 having the round ring shape. The first branched path 21a is formed so that a central part 23a of the first branched path 21a in the circumferential direction is disposed on an edge 15c of the internal circumference side of the gas inlet hole 12a. An opening hole 22a leading to the gas inlet hole 12a is formed on an external circumference side of the central part 23a of the first branched path 21a. The gas is introduced into the first branched path 21a from the gas inlet hole 12a via the opening hole 22a.

As shown by an arrow A₁, the gas introduced from the gas inlet hole 12a is separated in the central part 23a of the first branched path 21a in the circumferential direction, and is transferred in a circumferential direction indicated by an arrow A₂ and in the opposite circumferential direction indicated by an arrow A₃ in FIG. 1. Here, the central part 23a of the first branched path 21a in the circumferential direction is a branch point.

The second branched path 21b also has a circular arc shape, and extends along the body unit 13 having the round ring shape. Also, similar to the first branched path 21a, the circumferential distance of the second branched path 21b is ⅛ of the circumference of the body unit 13 having the round ring shape. The second branched path 21b is formed so that a central part 23b of the second branched path 21b in the circumferential direction is located at an end 24a of the first branched path 21a in the circumferential direction. An opening hole 22b leading to the end 24a of the first branched path 21a is formed in an outer diameter side of the central part 23b of the second branched path 21b in the circumferential direction. The gas is introduced from the first branched path 21a to the second branched path 21b via the opening hole 22b.

The gas introduced into the second branched path 21b is separated in the central part 23b of the second branched path 21b in the circumferential direction, and is transferred in a circumferential direction indicated by an arrow A₄ and in the opposite circumferential direction indicated by an arrow A₅ in FIG. 1. Then, the gas is ejected from the gas jets 18a and 18b opened in the internal circumference surface 14b of the body unit 13.

Referring to FIGS. 1 and 2, sections of the first and second branched paths 21a and 21b have rectangular shapes. Also, cross sections of the first and second branched paths 21a and 21b are formed to be the same in the circumferential direction. The first and second branched paths 21a and 21b having such rectangular shaped sections are formed by welding two quartz glass members. A method of manufacturing the gas ring 11 having such a structure will be described later.

The second branched path 21c is formed so that a central part 23c of the second branched path 21c in the circumferential direction is located at another end 24b of the first branched path 21a in the circumferential direction. An opening hole 22c leading to the end 24b of the first branched path 21a is formed in an external circumference side of the central part 23c of the second branched path 21c in the circumferential direction. The gas is introduced from the first branched path 21a to the second branched path 21c via the opening hole 22c.

The gas introduced into the second branched path 21c is separated in the central part 23c of the second branched path 21c in the circumferential direction, passes through the second branched path 21c, and is ejected from the gas jets 18c and 18d opened in the internal circumference surface 14b of the body unit 13. Since other structures of the second branched path 21c are identical to the structures of the second branched path 21b, descriptions thereof are not repeated.

Also, structures of the first branched path 21d and second branched paths 21e and 21f are respectively identical to the structures of the first branched path 21a and the second branched paths 21b and 21c, and the first branched path 21d leads to the second branched paths 21e and 21f by opening holes 22e and 22f, and thus descriptions thereof are omitted. In other words, the gas ring 11 is symmetrical in right and left directions, and top and bottom directions, as illustrated in FIG. 1.

Here, distances from the gas jets 18a through 18h to the central parts 23a and 23d, respectively, which are the branched points of the branched paths 21a through 21f, are the same. In detail, a distance from the gas jet 18a to the central part 23a as the branch point, a distance from the gas jet 18b to the central part 23a as the branch point, a distance from the gas jet 18c to the central part 23a as the branch point, a distance from the gas jet 18d to the central part 23a as the branch point, a distance from the gas jet 18e to the central part 23d as the branch point, a distance from the gas jet 18f to the central point 23d as the branch point, a distance from the gas jet 18g to the central part 23d as the branch point, and a distance from the gas jet 18h to the central part 23d as the branch point are the same.

In the gas ring 11 having such a structure, since the distances from the gas jets 18a through 18h to the central parts 23a and 23d, respectively, which are the branch points of the branched paths 21a through 21f, are the same, the pressure or flow rate of the gas ejected from each of the gas jets 18a through 18h are the same. Accordingly, the gas is uniformly ejected from each of the gas jets 18a through 18h.

Also, since the gas ring 11 has a round ring shape, the gas is uniformly ejected in the circumferential direction.

In addition, since the gas jets 18a through 18h are equally spaced apart from each other in the circumferential direction, the gas is uniformly ejected in the circumferential direction.

Also, in the above embodiment, flow passage resistance (conductance) from each of the gas jets 18a through 18h to the central parts 23a and 23d as the branched points, i.e., gas conductance in the branched paths, may be the same Here, a flow passage resistance in the first branched path 21a and a flow passage resistance in the first branched path 21d are the same. Also, a flow passage resistance in the second branched path 21b, a flow passage resistance in the second branched path 21c, a flow passage resistance in the second branched path 21e, and a flow passage resistance in the second branched path 21f are the same. Accordingly, the gas may be uniformly ejected.

In other words, a flow passage resistance in each of the gas jets 18a through 18h to the central parts 23a and 23d as the branch points is identical. Here, the sectional shapes shown in FIG. 2 are the same in each of the branched paths 21a through 21f. Accordingly, the gas may be uniformly ejected.

Also, in the above embodiment, each of the gas jets 18a through 18h has a circular shape, but the present invention is not limited thereto, and each of the gas jets 18a through 18h may have a rectangular shape, a polygonal shape, or the like.

Also, in the above embodiment, the second branched paths 21b, 21c, 21e, and 21f are disposed on the internal circumference sides of the first branched paths 21a and 21d, but the locations of the second branched paths 21b, 21c, 21e, and 21f are not limited thereto, and may be disposed in the same locations in a radial direction, i.e., the first branched paths 21a and 21d, and the second branched paths 21b, 21c, 21e, and 21f may be disposed above and below each other respectively.

Also, in the above embodiment, the gas ring 11 includes the first branched paths 21a and 21d, and the second branched paths 21b, 21c, 21e, and 21f branching from the first branched paths 21a and 21d, but the gas ring 11 is not limited thereto, and a third branched path additionally branching from the second branched paths 21b, 21c, 21e, and 21f or a fourth branched path additionally branching from the third branched path may be formed. In this case, for example, a length of a branched path in a circumferential direction may be 1/16 or 1/32 of the length of the body unit 13 in the circumferential direction.

Also, the number of gas inlet holes may be one. In this case, a first branched path has a semicircular shape with respect to the body unit 13 having the round ring shape.

Also, the number of gas jets may be more or less than eight. In this case, the number of gas jets may be at least three. Also, with the third and fourth branched paths, 16 or 32 gas jets that are equally spaced apart from each other may be formed, thereby realizing minute pressure uniformity or the like of the gas.

Here, the method of manufacturing the gas ring 11 will now be described with reference to FIG. 3. First, a quartz glass plate 25a having a thickness L₁, and a quartz glass plate 25b having a thickness L₂, wherein the thickness L₂ is greater than the thickness L₁, are prepared. Then, an external shape of the quartz glass plate 25a having the thickness L₁ is processed to have a ring shape as illustrated in FIG. 1. Meanwhile, the quartz glass plate 25b having the thickness L₂ is first cut from a surface 26b thereof to a depth L₃ so as to form first and second branched paths. Here, the quartz glass plate 25b having the thickness L₂ is processed, for example, using a cutting process. Then, as described above, an external shape of the quartz glass plate 25b is processed to have a ring shape as illustrated in FIG. 1 and to form gas jets. Next, the quartz glass plates 25a and 25b are welded to each other so that a surface 26a and the surface 26b face each other. Then, the gas ring 11 is manufactured by attaching the gas inlet holes 12a and 12b to the welded quartz glass plates 25a and 25b.

As such, the gas ring 11 may be precisely manufactured. Accordingly, ejection uniformity of a gas may be sufficiently secured.

A plasma processing apparatus as an apparatus for processing a semiconductor substrate including the gas ring 11 will now be described.

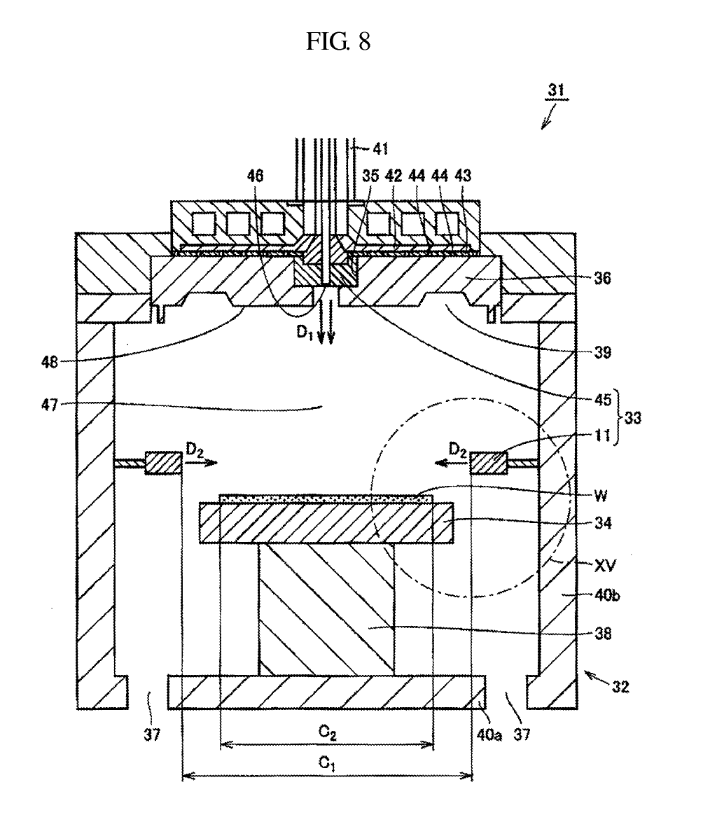

FIG. 8 is a cross-sectional view schematically illustrating main parts of a plasma processing apparatus 31 as an apparatus for processing a semiconductor substrate including the gas ring 11, according to an embodiment of the present invention. Referring to FIG. 8, the plasma processing apparatus 31 includes a processing container 32, in which a plasma process is performed on a substrate W to be processed into a semiconductor substrate, a holding stage 34, which has a circular plate shape, disposed inside the processing container 32 and on a holding unit 38 that is formed to extend from a center of a bottom part 40a of the processing container 32 in an upward direction in the processing container 32, and holds the substrate W using an electrostatic chuck, a microwave generator (not shown), which includes a high frequency wave supply source (not shown), etc., and generates microwaves for exciting plasma, a dielectric plate 36, which is disposed at a location facing the holding stage 34 and transmits microwaves generated by the microwave generator into the processing container 32, a reaction gas supplier 33, which supplies a reaction gas for plasma-processing plasma toward the substrate W held by the holding stage 34, and a controller (not shown), which controls the entire plasma processing apparatus 31. The microwave generator and the dielectric plate 36 are plasma generating means for generating plasma in the processing container 32.

The controller controls process conditions for plasma-processing the substrate W, such as a gas flow rate in the reaction gas supplier 33, a pressure in the processing container 32, etc. The reaction gas supplied by the reaction gas supplier 33 is uniformly supplied to a center area and an edge area around the center area of the substrate W. A detailed structure of the reaction gas supplier 33 will be described later.

The processing container 32 includes the bottom part 40a, and a side wall 40b that extends from a circumference of the bottom part 40a in an upward direction. An upper side of the processing container 32 is opened, and may be sealed by the dielectric plate 36 disposed on the upper side of the processing container 32 and a sealing member (not shown). The plasma processing apparatus 31 includes a vacuum pump (not shown) and an exhaust pipe (not shown), and thus the pressure inside the processing container 32 may be adjusted to a predetermined value via depressurization. Also, an exhaust port 37 connected to the exhaust pipe is formed to open a part of the bottom part 40a disposed on a bottom side of the holding stage 34.

A heater (not shown) that heats the substrate W to maintain the substrate W at a predetermined temperature during the plasma process is disposed inside the holding stage 34. The microwave generator includes a high frequency wave supply source (not shown). Also, another high frequency wave supply source (not shown) that arbitrarily applies a bias voltage during the plasma-process is connected to the holding stage 34.

The dielectric plate 36 has a circular plate shape, and is formed of a dielectric material. A concave unit 39, having a ring shape and sunken in a taper shape for easily generating standing waves by using the transferred microwaves, is formed on a bottom surface of the dielectric plate 36. By using the concave unit 39, plasma may be efficiently generated on the bottom side of the dielectric plate 36 by using the microwaves.

The plasma processing apparatus 31 includes a waveguide 41, which transmits the microwaves generated by the microwave generator into the processing container 32, a wavelength-shortening plate 42, which propagates the microwaves, and a slot antenna 44, which has a thin circular plate shape and transfers the microwaves to the dielectric plate 36 through a plurality of slot holes 43 formed therein. The microwaves generated by the microwave generator propagate to the wavelength-shortening plate 42 via the waveguide 41, and are transferred to the dielectric plate 36 from the plurality of slot holes 43 formed in the slot antenna 44. An electric field is generated right below the dielectric plate 36 by the microwaves transferred to the dielectric plate 36, and thus plasma is generated in the processing container 32 via plasma ignition.

A detailed structure of the reaction gas supplier 33 will now be described. The reaction gas supplier 33 includes an injector 45, which ejects the reaction gas toward a center area of the substrate W held by the holding stage 34, and the gas ring 11, which has a round ring shape and the structure shown in FIGS. 1 through 7, and ejects the reaction gas toward an edge area of the substrate W held by the holding stage 34.

An accommodating unit 35, which accommodates the injector 45, is formed in the center of the dielectric plate 36 and penetrates the dielectric plate 36 in the thickness direction thereof. The injector 45 is accommodated in the accommodating unit 35. The injector 45 ejects the reaction gas for the plasma process toward the center area of the substrate W via a plurality of holes 46 formed in a facing surface that faces the holding stage 34. The holes 46 are formed in a side of the dielectric plate 36 that is further away from substrate W than a bottom surface 48 of the dielectric plate 36 facing the holding stage 34. Also, a direction of the reaction gas ejected from the injector 45 is indicated by an arrow D₁.

The gas ring 11 is formed so that the supports 16a and 16b are attached to the side wall 40b of the processing container 32. An internal diameter C₁ of the gas ring 11 is formed to be greater than an outer diameter C₂ of the substrate W held on the holding stage 34. A direction of the reaction gas ejected from the gas ring 11 is indicated by an arrow D₂.

Also, the reaction gas for processing the substrate W and gas (argon) for exciting plasma are supplied to the injector 45 and the gas ring 11.

Then, a method of plasma-processing the substrate W by using the plasma processing apparatus 31 including the gas ring 11, according to an embodiment of the present invention, will now be described.

First, the plasma processing apparatus 31 having the above structure is prepared. In other words, the plasma processing apparatus 31, which includes the reaction gas supplier 33 that includes the injector 45 ejecting the reaction gas toward the center area of the substrate W held by the holding stage 34, and the gas ring 11 having the above structure and ejecting the reaction gas toward the edge area of the substrate W held by the holding stage 34, is prepared. Here, the reaction gas includes a gas for forming a layer, a cleaning gas, an etching gas, or the like.

Then, the substrate W to be processed into a semiconductor substrate is held on the holding stage 34. Next, the processing container 32 is depressurized to a predetermined pressure. Then, a gas for exciting plasma is introduced into the processing container 32, and microwaves for exciting plasma are generated by the microwave generator and transferred into the processing container 32 via the dielectric plate 36. Accordingly, plasma is generated in the processing container 32. Here, the plasma is generated right below the dielectric plate 36. The generated plasma is diffused to an area below a bottom surface of the dielectric plate 36.

Then, the reaction gas is supplied by the reaction gas supplier 33. In detail, the injector 45 ejects the reaction gas toward the center area of the substrate W held by the holding stage 34, and then the gas ring 11 ejects the reaction gas toward the edge area of the substrate W held by the holding stage 34. Accordingly, the substrate W is plasma-processed.

Here, an internal diameter of the gas ring 11 having the round ring shape is greater than an outer diameter of the substrate W held on the holding stage 34, so that the gas ring 11 is disposed at a location other than an area 47 right above the substrate W, thereby removing a shielding in the area 47 right above the substrate W. Accordingly, the plasma in the area 47 right above the substrate W is uniform. Also, the reaction gas may be uniformly ejected to each part of the substrate W by using the gas ring 11 and the injector 45 having the above structure. Accordingly, a processing speed distribution of the substrate W may be uniform.

Also, in the gas ring 11 having the above structure, the gas jets 18a through 18h are formed on the internal circumference surface 14b of the body unit 13, but the gas jets 18a through 18h may be formed on a bottom surface of the body unit 13. In detail, the gas jets 18a through 18h may be formed on a surface 26c illustrated in FIG. 3. Accordingly, a gas is ejected in a downward direction, thereby ejecting the reaction gas to the substrate W. Also, the gas jets 18a through 18h may be formed so that a gas is ejected in a slightly tilted downward direction toward the edge area of the substrate W. In detail, for example, the gas jets 18a through 18h may be formed on edge portions formed between the surface 26c and the internal circumference surface 14b.

Also, by adjusting diameters of the gas jets 18a through 18h, a gas pressure, a gas flow rate, or the like, the reaction gas may be uniformly ejected toward each part of the substrate W, without ejecting a gas from the injector 45.

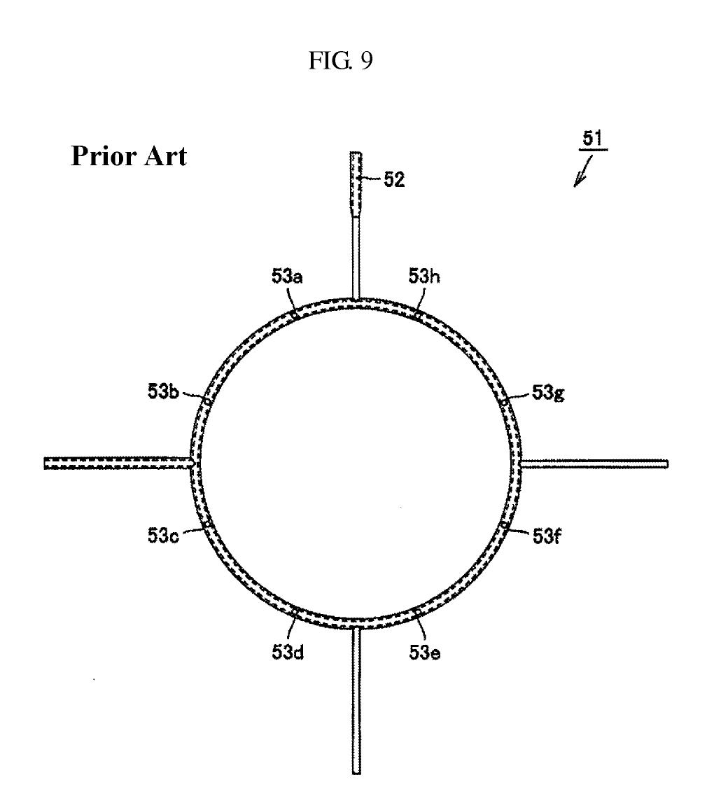

A difference between a semiconductor substrate on which a CVD process is performed using the plasma processing apparatus 31 described above and a semiconductor substrate on which a CVD process is performed using a conventional processing apparatus will now be described. FIG. 9 is a diagram illustrating a gas ring 51 included in the conventional processing apparatus. Referring to FIG. 9, the gas ring 51 includes one gas inlet hole 52 and 8 gas jets 53a, 53b, 53c, 53d, 53e, 53f, 53g, and 53h. The gas jets 53a through 53h are equally spaced apart from each other. Distances from the gas inlet hole 52 to each of the gas jets 53a through 53h may be identical or different from each other.

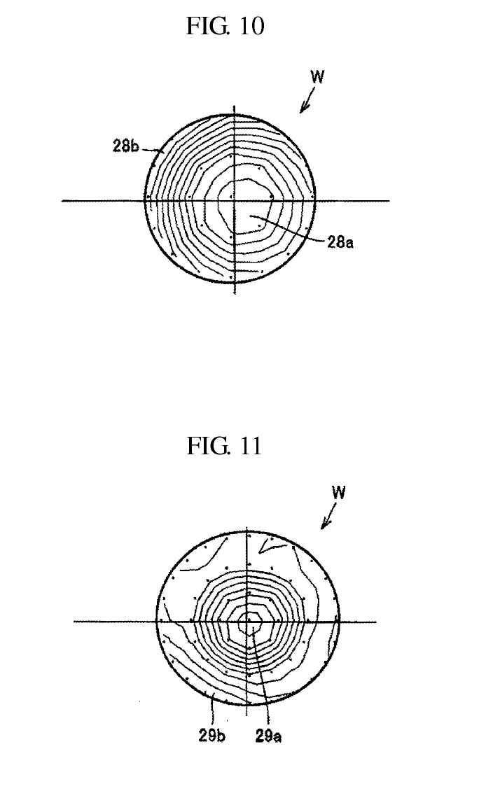

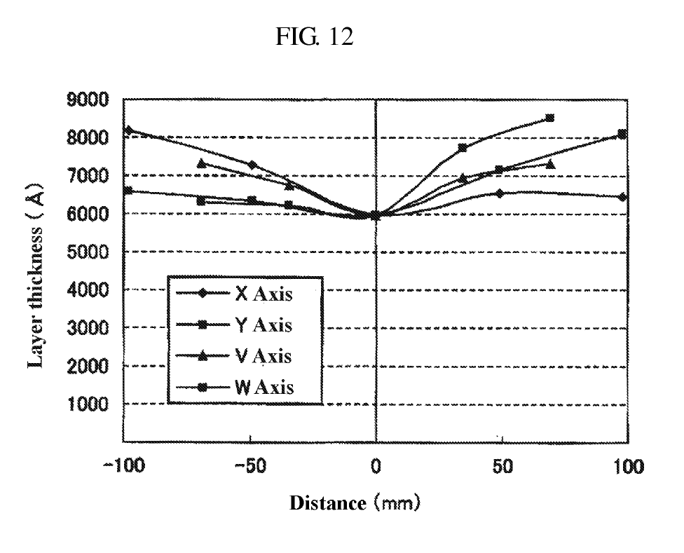

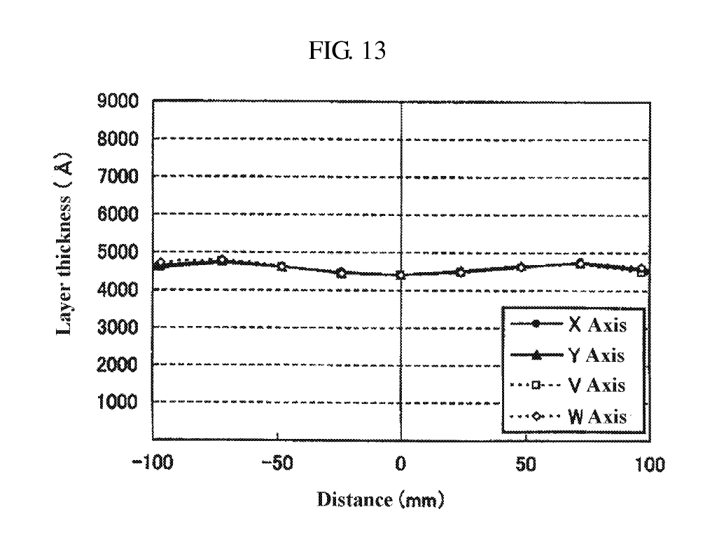

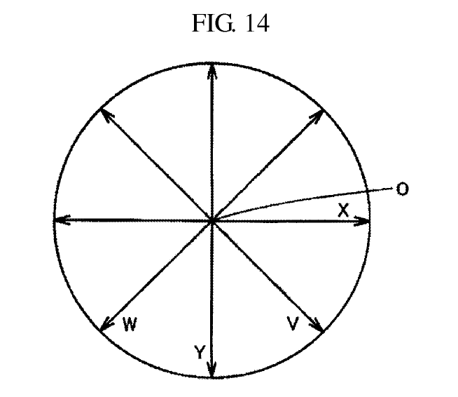

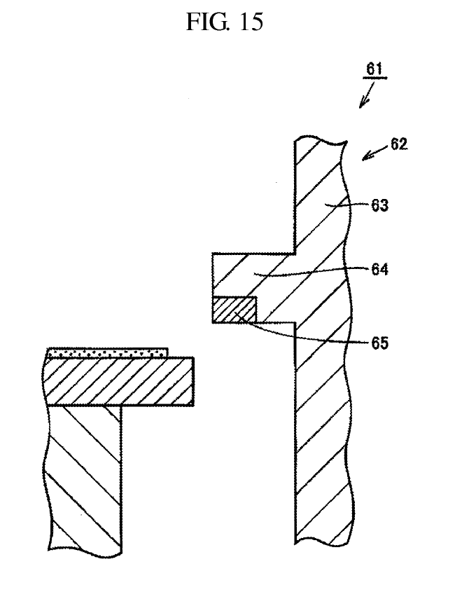

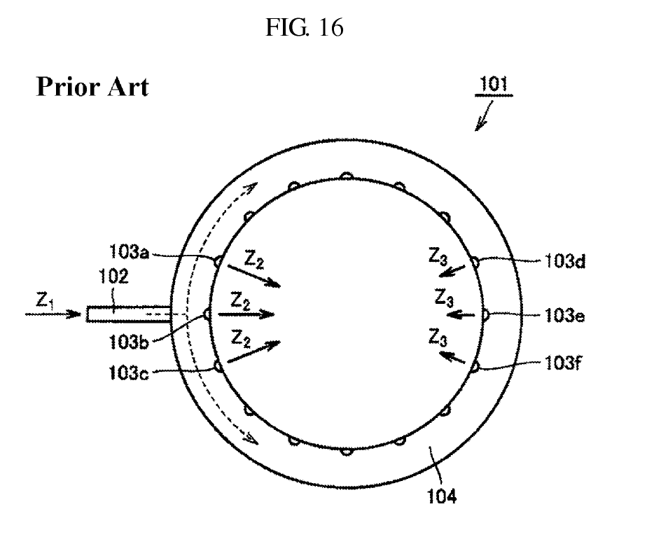

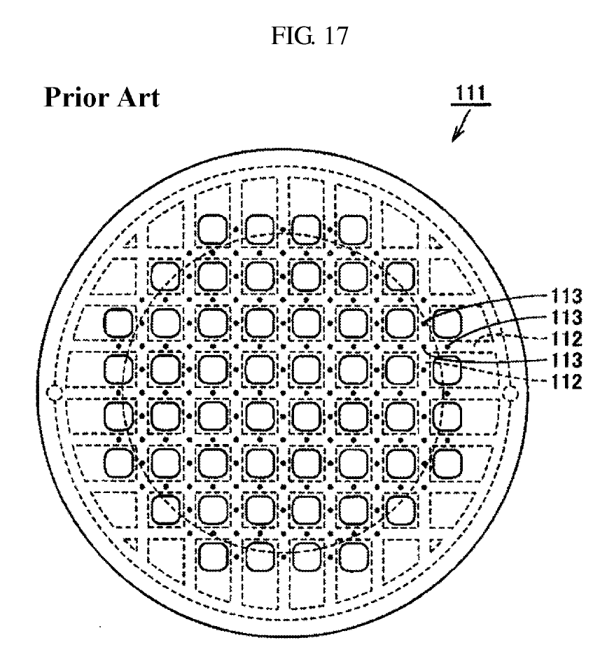

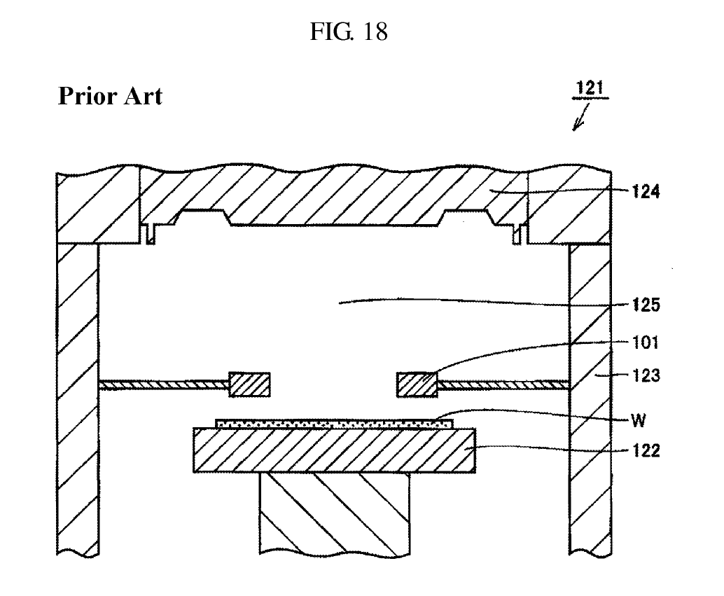

FIG. 10 is a diagram showing a thickness distribution of a layer of a semiconductor substrate when a CVD process is performed by using the conventional processing apparatus including the gas ring 51 of FIG. 9. In FIG. 10, an area 28a indicates an area close to the center (O), and an area 28b indicates an edge area far from the center (O). FIG. 11 is a diagram showing a thickness distribution of a layer of a semiconductor substrate when a CVD is performed by using the plasma processing apparatus 31. In FIG. 11, an area 29a indicates an area close to the center (O), and an area 29b indicates an edge area far from the center (O). FIG. 12 is a graph of a layer thickness with respect to a location of the layer on the semiconductor substrate of FIG. 10. FIG. 13 is a graph of a layer thickness with respect to a location of the layer on the semiconductor substrate of FIG. 11. In FIGS. 12 and 13, the Y-axis is the layer thickness (A) and the X-axis is a distance (mm) from the center (O). FIG. 14 is a diagram showing the X-axis, Y-axis, V-axis, and W-axis of FIGS. 12 and 13 indicated on a semiconductor substrate. In both cases, an SiO layer is formed by using a mixed gas, that is, a reaction gas (process gas), including tetraethylorthosilicate (TEOS), oxygen, and argon, as a reaction gas (process gas). Also, a layer forming pressure during processing of the semiconductor substrate of FIG. 10 was 65 mtorr, and a layer forming pressure during processing of the semiconductor substrate of FIG. 11 was 360 mtorr.

Also, a layer forming rate during processing of the semiconductor substrate of FIG. 10 was 3600 Å/min., and a layer forming rate during processing of the semiconductor substrate of FIG. 11 was 4000 Å/min. Also, a (un-uniformity) was 4.4% in the semiconductor substrate of FIG. 10, and 2.9% in the semiconductor substrate of FIG. 11. Here, when a layer forming pressure decreases, uniformity on a wafer surface of a layer forming rate increases.

Referring to FIGS. 9 through 14, when the layer is formed by using the conventional processing apparatus, the layer thickness changes toward a substrate edge, and the layer thickness is non-uniform along each axis. However, when the layer is formed by using the plasma processing apparatus 31 having the above structure, a layer thickness difference between a substrate edge and a substrate center is small, and non-uniformity of the layer thickness along each axis is low. Uniformity in a surface, here, as shown in FIGS. 10 and 11, the uniformity of the layer thickness is better in the case when the plasma processing apparatus 31, as shown in FIG. 11, is used, than in the case when the conventional processing apparatus, as shown in FIG. 10 is used.

As such, according to the plasma processing apparatus 31, a uniform layer may be formed via a CVD process using the plasma processing apparatus.

Also, in the plasma processing apparatus 31, the gas ring 11 may be embedded in the side wall 40b of the processing container 32. FIG. 15 is a cross-sectional view of a part of a plasma processing apparatus 61 in this case, and corresponds to an area XV of FIG. 8. Referring to FIG. 15, a side wall 63 of a processing container 62 included in the plasma processing apparatus 61 includes a protruding unit 64 that protrudes toward an internal diameter side. Also, a gas ring 65 is embedded in a part of the protruding unit 64. In such a structure, the above effects may be achieved.

In the above embodiment, a gas ring has a round ring shape, but the shape of the gas ring is not limited thereto, and may be, for example, a rectangular ring shape having a straight line, a polygonal ring shape, or another ring shape. Also, a material of the gas ring may be alumina.

Also, in the above embodiment, two quartz glass plates are welded so as to form the gas ring, but a method of forming the gas ring is not limited thereto, and the gas ring may be formed by welding two or more quartz glass plates. Also, for example, the gas ring having the above structure may be formed by preparing a plurality of glass pipes and bending the glass pipes into, for example, circular arc shapes.

Also, in the above embodiment, an injector is used in the plasma processing apparatus, but the plasma processing apparatus is not limited thereto, and the plasma processing apparatus may not include an injector. In other words, in the plasma processing apparatus, a reaction gas or the like may be supplied by only a gas ring according to an embodiment of the present invention.

Also, in the above embodiment, a plasma CVD process is performed, but the performed process is not limited thereto, and a plasma etching process may be performed.

Also, in the above embodiment, a plasma processing apparatus uses microwaves as a plasma source, but the plasma source is not limited thereto, and inductively-coupled plasma (ICP) or electron cyclotron resonance (ECR) plasma, or parallel flat board type plasma may be used as the plasma source.

Also, in the above embodiment, a gas ring is used as a reaction gas supplying member that supplies a reaction gas in the plasma processing apparatus, but the gas ring is not limited thereto, and may be used in an apparatus for processing a semiconductor substrate with means other than plasma. Also, the gas ring may be used in another apparatus that supplies a gas by ejecting the gas.

According to such a gas ring, since distances from each gas jet to branch points of each branched path are the same, a pressure or a flow rate of gas ejected from each gas jet may be uniform. Accordingly, gas is uniformly ejected from each gas jet.

Also, according to such an apparatus for processing a semiconductor substrate, a gas ring is disposed at a location other than an area right above a substrate to be processed, and thus a shielding above the area right above the substrate to be processed may be removed. Accordingly, plasma in the area right above the substrate to be processed may be uniform. Also, by using the gas ring and an injector having the above structure, a reaction gas may be uniformly ejected to each area of the substrate to be processed. Accordingly, processing speed distribution of the substrate to be processed may be uniform.

Also, according to such a method of processing a semiconductor substrate, a reaction gas may be uniformly ejected onto a substrate to be processed, and thus the semiconductor substrate may be uniformly processed.

A gas ring according to the present invention is included in an apparatus for processing a semiconductor substrate, and is efficiently used when a reaction gas is supplied by ejecting the reaction gas.

An apparatus for and method of processing a semiconductor substrate according to the present invention may be efficiently used when processing speed distribution of the semiconductor substrate is required to be uniform.

While this invention has been particularly shown and described with reference to exemplary embodiments thereof, it will be understood by those skilled in the art that various changes in form and details may be made therein without departing from the spirit and scope of the invention as defined by the appended claims.

What is claimed is:

1. A gas ring having a ring shape, the gas ring comprising:
a gas inlet hole through which a gas is introduced from outside the gas inlet hole into the gas ring;
a plurality of gas jets that eject the gas introduced from the gas inlet hole;
a plurality of branched paths extending along the ring shape from the gas inlet hole to each of the plurality of gas jets,
wherein distances between each of the plurality of gas jets to branch points of each of the plurality of branched paths are identical to each other.

2. The gas ring of claim 1, wherein the gas ring has a round ring shape.

3. The gas ring of claim 1, wherein the plurality of gas jets are equally spaced apart from each other.

4. The gas ring of claim 1, wherein flow passage resistances from each of the plurality of gas jets to the branch points are the same.

5. The gas ring of claim 1, wherein each of the plurality of gas jets has a circular shape, and diameters of the plurality of gas jets having the circular shape are the same.

6. An apparatus for processing a semiconductor substrate, the apparatus comprising:
a processing container for processing a substrate to be processed inside the processing container;
a holding stage that is disposed inside the processing container and holds the substrate to be processed thereon;
a plasma generating means that generates plasma inside the processing container; and
a reaction gas supplier that supplies a reaction gas for a process toward the substrate to be processed held by the holding stage,
wherein the reaction gas supplier comprises:
an injector that ejects the reaction gas toward a center area of the substrate to be processed held by the holding stage; and
the gas ring of claim 1 that ejects the reaction gas toward an edge area of the substrate to be processed held by the holding stage,
wherein the gas ring is disposed at a location other than an area right above the substrate to be processed held by the holding stage.

7. The apparatus of claim 6, wherein the plasma generating means comprises:
a microwave generator that generates microwaves for exciting plasma; and
a dielectric plate that is disposed at a location facing the holding stage and transfers the microwaves into the processing container.

8. The apparatus of claim 6, wherein the substrate to be processed has a circular plate shape, the gas ring has a circular ring shape, and an internal diameter of the gas ring is greater than an outer diameter of the substrate to be processed.

9. The apparatus of claim 6, wherein the processing container comprises a bottom part disposed below the holding stage and a side wall extending upwardly from a circumference of the bottom part, and the gas ring is embedded inside the side wall.

10. A method of processing a semiconductor substrate, whereby the semiconductor substrate is manufactured by processing a substrate to be processed, the method comprising:
preparing an injector, which ejects a reaction gas for a process toward a center area of the substrate to be processed, and the gas ring of claim 1, which ejects the reaction gas toward an edge area of the substrate to be processed;
holding the substrate to be processed on a holding stage disposed inside a processing container;
generating plasma inside the processing container; and
ejecting the reaction gas from the injector and the gas ring toward the substrate to be processed, and processing the substrate to be processed by using the generated plasma.
